(19) United States
(12) Patent Application Publication
(10) Pub. No.: US 2023/0298885 A1
(43) Pub. Date: Sep. 21, 2023

(54) METHODS FOR DEPOSITING GAP-FILLING FLUIDS AND RELATED SYSTEMS AND DEVICES

(71) Applicant: ASM IP Holding, B.V., Almere (NL)

(72) Inventors: Ranjit Borude, Nagoya (JP); Shinya Yoshimoto, Tokyo (JP); Makoto Igarashi, Tokyo (JP); Jhoelle Roche Guhit, Tokyo (JP); Pamarti Viswanath, Tokyo (JP)

(21) Appl. No.: 18/185,625

(22) Filed: Mar. 17, 2023

Related U.S. Application Data
(60) Provisional application No. 63/321,388, filed on Mar. 18, 2022.

(51) Int. Cl. H01L 21/02; H01J 37/32; C23C 16/34; C23C 16/455

(52) U.S. Cl. CPC H01L 21/02348; H01J 37/32449; H01J 37/32899; H01L 21/0217; H01L 21/02274; H01L 21/0228; H01L 21/02337; H01L 21/02222; C23C 16/345; C23C 16/45536; C23C 16/45553; H01J 37/32357; H01J 2237/332; H01J 37/32733

(57) ABSTRACT

Methods and related systems for at least partially filling recesses comprised in a substrate with a gap filling fluid. The gap filling fluid comprises a Si—N bond. The methods comprise exposing the substrate to a nitrogen and hydrogen-containing gas on the one hand and to vacuum ultraviolet light on the other hand.

### FIELD OF INVENTION

The present disclosure generally relates to methods and systems suitable for forming electronic devices. More particularly, the disclosure relates to methods and systems that can be used for improving materials that were deposited in gaps, trenches, and the like.

### BACKGROUND OF THE DISCLOSURE

The scaling of semiconductor devices has led to significant improvements in speed and density of integrated circuits. However, with miniaturization of wiring pitch of large scale integration devices, void-free filling of high aspect ratio trenches (e.g. trenches having an aspect ratio of three or higher) becomes increasingly due to limitations of existing deposition processes. Therefore, there remains a need for processes that efficiently fill high aspect ratio features, e.g. gaps such as trenches on semiconductor substrates.

Any discussion, including discussion of problems and solutions, set forth in this section has been included in this disclosure solely for the purpose of providing a context for the present disclosure. Such discussion should not be taken as an admission that any or all of the invention was previously known or otherwise constitutes prior ar.

### SUMMARY OF THE DISCLOSURE

Various embodiments of the present disclosure relate to gap filling methods, to structures and devices formed using such methods, and to apparatus for performing the methods and/or for forming the structure and/or devices. The ways in which various embodiments of the present disclosure address drawbacks of prior methods and systems are discussed in more detail below.

In particular, described herein is a method of curing a gap filling fluid. The method comprises introducing a substrate provided with a gap in a process chamber. The gap comprises a gap filling fluid. The gap filling fluid comprises a Si—N bond. The method further comprises simultaneously exposing the substrate to vacuum ultraviolet radiation and to an ambient gas. The ambient gas may comprise nitrogen and hydrogen-containing gas or argon-containing gas. Thus, the gap filling fluid is cured and silicon nitride is formed in the gap.

Further described herein is a method of filling a gap. The method comprises introducing a substrate provided with a gap into a process system. The method comprises executing one or more cycles. A cycle comprises a deposition step and a curing step. The deposition step comprises providing a precursor. The precursor comprises silicon, nitrogen, and hydrogen. The method further comprises providing a reactant. The reactant comprises one or more of nitrogen, hydrogen, and a noble gas. The method further comprises generating a plasma. The plasma causes the precursor and the reactant to react to form a gap filling fluid that at least partially fills the gap. The gap filling fluid comprises a Si—N bond. The curing step comprises simultaneously exposing the substrate to vacuum ultraviolet radiation and to an ambient gas. The ambient gas may comprise nitrogen and hydrogen-containing gas or argon containing gas. Thus, the gap filling fluid is cured and silicon nitride is formed in the gap.

In some embodiments, a method as described herein comprises executing a plurality of cycles. Thus, a gap can be at least partially filled with silicon nitride.

In some embodiments, the nitrogen and hydrogen-containing gas comprises NH₃.

In some embodiments, the gap filling fluid comprises a polysilazane.

In some embodiments, the precursor comprises a silazane.

In some embodiments, the precursor comprises a compound having the formula

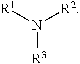

It shall be understood that R¹, R², and R³ are independently selected from SiH₃, SiH₂X, SiH₂XY, SiX₂Y, and SiX₃. It shall be further understood that X is a first halogen, and that Y is a second halogen.

In some embodiments, R¹, R², and R³ are SiH₃.

In some embodiments, the precursor comprises a compound having the formula

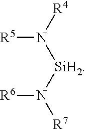

It shall be understood that R⁴, R⁵, R⁶, and R⁷ are independently selected from H, SiH₃, SiH₂X, SiHXY, SiX₂Y, and SiX₃. It shall be further understood that X is a first halogen, and that Y is a second halogen.

In some embodiments, the precursor comprises a compound having the formula

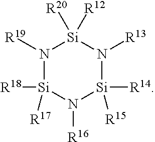

It shall be understood that R¹², R¹³, R¹⁴, R¹⁵, R¹⁶, R¹⁷, R¹⁸, R¹⁹, and R²⁰ are independently selected from the list consisting of H, X, Y, NH₂, SiH₃, SiH₂X, SiHXY, SiX₂Y, and SiX₃. In some embodiments, X is a first halogen, and Y is a second halogen.

In some embodiments, the deposition step and the curing step are carried out in the same process system, without any intervening vacuum break.

In some embodiments, the vacuum ultraviolet radiation comprises electromagnetic radiation having a wavelength of at least 150 nm to at most 200 nm.

In some embodiments, the deposition step is carried out in a first process chamber and the curing step is carried out in a second process chamber. It shall be understood that the first process chamber and the second process chamber are different process chambers comprised in the same process system.

In some embodiments, the deposition step is carried out at a deposition temperature of at most 150° C.

In some embodiments, the curing step is carried out at a curing temperature which is at most 20° C. higher than the deposition temperature.

In some embodiments, a method as described herein further comprises a step of annealing the substrate at an annealing temperature, the annealing temperature being higher than the deposition temperature.

Further described herein is a processing system. The processing system comprises a first process chamber, a precursor source, a precursor line, an ammonia source, an ammonia line, and a vacuum ultraviolet light source. The precursor source comprises a precursor. The precursor comprises a Si—N bond. The precursor line is arranged for providing the precursor from the precursor source to the first process chamber. The ammonia line is arranged for providing ammonia from the ammonia source to the first process chamber. The vacuum ultraviolet light source is arranged for generating vacuum ultraviolet light.

In some embodiments, the processing system further comprises a second process chamber and a wafer handling system. In such embodiments, the vacuum ultraviolet light source can be arranged for providing vacuum ultraviolet light to the second process chamber, and the wafer handling system can be arranged for transporting one or more wafers between the first process chamber and the second process chamber.

In some embodiments, the processing system further comprises a controller. The controller is arranged for causing the processing system to carry out a method as described herein.

These and other embodiments will become readily apparent to those skilled in the art from the following detailed description of certain embodiments having reference to the attached figures. The invention is not limited to any particular embodiments disclosed.

### BRIEF DESCRIPTION OF THE DRAWING FIGURES

A more complete understanding of the embodiments of the present disclosure may be derived by referring to the detailed description and claims when considered in connection with the following illustrative figures.

FIG. 1 is a schematic representation of a plasma-enhanced atomic layer deposition (PEALD) apparatus suitable for depositing a structure and/or for performing a method in accordance with at least one embodiment of the present disclosure.

FIGS. 2(a) and 2(b) illustrate a schematic representation of a precursor supply system using a flow-pass system (FPS) usable in accordance with at least one embodiment of the present disclosure.

FIG. 3 shows a schematic representation of an embodiment of a direct plasma system that is operable or controllable to form a gap filling fluid.

FIG. 4 shows a schematic representation of another embodiment of an indirect plasma system operable or controllable to form a gap filling fluid.

FIG. 5 shows a schematic representation of an embodiment of a remote plasma system operable or controllable to form a gap filling fluid.

FIG. 6 shows an exemplary embodiment of a method for curing a gap filling fluid as described herein.

FIG. 7 shows another exemplary embodiment of a method for curing a gap filling fluid as described herein.

FIGS. 8(a)-8(c) show exemplary pulsing schemes that can be used for forming gap filling fluids in one or more embodiments of methods as described herein.

FIG. 9 shows another exemplary pulsing scheme that can be used for forming a gap filling fluid in one or more embodiments of methods as described herein.

FIG. 10 schematically shows a layout of an exemplary system according to an embodiment of the present disclosure.

FIGS. 11(a)-11(d) shows experimental results.

FIG. 12 shows another exemplary embodiment of a method for curing a gap filling fluid as described herein.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

The description of exemplary embodiments of methods, structures, devices and systems provided below is merely exemplary and is intended for purposes of illustration only; the following description is not intended to limit the scope of the disclosure or the claims. Moreover, recitation of multiple embodiments having stated features is not intended to exclude other embodiments having additional features or other embodiments incorporating different combinations of the stated features. For example, various embodiments are set forth as exemplary embodiments and may be recited in the dependent claims. Unless otherwise noted, the exemplary embodiments or components thereof may be combined or may be applied separate from each other.

In this disclosure, “gas” can include material that is a gas at normal temperature and pressure (NTP), a vaporized solid and/or a vaporized liquid, and can be constituted by a single gas or a mixture of gases, depending on the context. A gas other than the process gas, i.e., a gas introduced without passing through a gas distribution assembly, a multi-port injection system, other gas distribution device, or the like, can be used for, e.g., sealing the reaction space, and can include a seal gas, such as a noble gas. In some cases, the term “precursor” can refer to a compound that participates in the chemical reaction that produces another compound, and particularly to a compound that constitutes a film matrix or a main skeleton of a film; the term “reactant” may be used interchangeably with the term precursor.

In some embodiments, the term “reactant” refers to a gas which can react and/or interact with a precursor in order to form a flowable gap fill layer as described herein. The reactant may activate precursor oligomerization. The reactant may be a catalyst. The reactant does not necessarily have to be incorporated in the gap filling fluid which is formed, though the reactant does interact with the precursor during formation of the gap filling fluid. In other words, in some embodiments the reactant is incorporated in the gap filling fluid whereas in other embodiments, the reactant is not incorporated in the gap filling fluid. Possible reactants include N₂, H₂, and NH₃ and noble gasses such as He and Ar, which can be brought in an excited state, in particular an excited state such as ion and/or radical induced by means of a plasma.

As used herein, the term “substrate” may refer to any underlying material or materials that can be used, or upon which, a device, a circuit, or a film may be formed. The “substrate” may be continuous or non-continuous; rigid or flexible; solid or porous. The substrate may be in any form such as a powder, a plate, or a workpiece.

In some embodiments, the term “substrate” can refer to any underlying material or materials that can be used to form a device, a circuit, or a film, or upon which a device, a circuit, or a film can be formed. A substrate can include a bulk material, such as silicon (e.g., single-crystal silicon), other Group IV materials, such as germanium, or other semiconductor materials, such as a Group II-VI or Group III-V semiconductor, and can include one or more layers overlying or underlying the bulk material.

A porous substrate may comprise polymers. Workpieces may comprise medical devices (i.e. stents, syringes, etc.), jewelry, tooling devices, components for battery manufacturing (i.e., anodes, cathodes, or separators) or components of photovoltaic cells.

A continuous substrate may extend beyond the bounds of a process chamber where a deposition process occurs and may move through the process chamber such that the process continues until the end of the substrate is reached. A continuous substrate may be supplied from a continuous substrate feeding system allowing for manufacture and output of the continuous substrate in any appropriate form. Non-limiting examples of a continuous substrate may include a sheet, a non-woven film, a roll, a foil, a web, a flexible material, a bundle of continuous filaments or fibers (i.e. ceramic fibers or polymer fibers). Continuous substrates may also comprise carriers or sheets upon which non-continuous substrates are mounted.

Further, in this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, or the like. Further, in this disclosure, the terms “including,” “constituted by” and “having” refer independently to “typically or broadly comprising,” “comprising,” “consisting essentially of,” or “consisting of” in some embodiments. In this disclosure, any defined meanings do not necessarily exclude ordinary and customary meanings in some embodiments.

As used herein, the term “comprising” indicates that certain features are included, but that it does not exclude the presence of other features, as long as they do not render the claim unworkable. In some embodiments, the term “comprising” includes “consisting”.

As used herein, the term “consisting” indicates that no further features are present in the apparatus/method/product apart from the ones following said wording. When the term “consisting” is used referring to a chemical compound, substance, or composition of matter, it indicates that the chemical compound, substance, or composition of matter only contains the components which are listed. This notwithstanding, the chemical compound, substance, or composition of matter may, in some embodiments, comprise other components as trace elements or impurities, apart from the components which are listed.

A gap in a substrate may refer to a patterned recess, trench, hole, or via in a substrate. A recess can refer to a feature between adjacent protruding structures and any other recess pattern may be referred to as a “trench”. That is, a trench may refer to any recess pattern including a hole/via. A trench can have, in some embodiments, a width of about 5 nm to about 150 nm, or about 30 nm to about 50 nm, or about 5 nm to about 10 nm, or about 10 nm to about 20 nm, or about 20 nm to about 30 nm, or about 50 nm to about 100 nm, or about 100 nm to about 150 nm. When a trench has a length that is substantially the same as its width, it can be referred to as a hole or a via. Holes or vias typically have a width of about 20 nm to about 100 nm. In some embodiments, a trench has a depth of about 30 nm to about 100 nm, and typically of about 40 nm to about 60 nm. In some embodiments, a trench has an aspect ratio of about 2 to about 10, and typically of about 2 to about 5. The dimensions of the trench may vary depending on process conditions, film composition, intended application, etc.

In some embodiments, the gap has a depth of at least 5 nm to at most 500 nm, or of at least 10 nm to at most 250 nm, or from at least 20 nm to at most 200 nm, or from at least 50 nm to at most 150 nm, or from at least 100 nm to at most 150 nm.

In some embodiments, the gap has a width of at least 10 nm to at most 10 000 nm, or of at least 20 nm to at most 5 000 nm, or from at least 40 nm to at most 2 500 nm, or from at least 80 nm to at most 1000 nm, or from at least 100 nm to at most 500 nm, or from at least 150 nm to at most 400 nm, or from at least 200 nm to at most 300 nm.

In some embodiments, the gap has a length of at least 10 nm to at most 10 000 nm, or of at least 20 nm to at most 5 000 nm, or from at least 40 nm to at most 2 500 nm, or from at least 80 nm to at most 1000 nm, or from at least 100 nm to at most 500 nm, or from at least 150 nm to at most 400 nm, or from at least 200 nm to at most 300 nm.

In some embodiments, the term “gap filling fluid”, also referred to as “flowable gap fill”, may refer to an oligomer which is liquid under the conditions under which is deposited on a substrate and which has the capability to cross link and form a solid film.

Methods as described can be useful for filling gaps with a gap filling fluid that is then cured. The gap filling fluid can be applied to various semiconductor devices including, but not limited to, cell isolation in 3D cross point memory devices, self-aligned via, dummy gate, reverse tone patterning, PC RAM isolation, cut hard mask, and DRAM storage node contact (SNC) isolation.

Thus, described herein is a method of curing a gap filling fluid. The method comprises introducing a substrate in a process chamber. The substrate is provided with a gap. The gap comprises a gap filling fluid. The gap filling fluid comprises a Si—N bond. The method further comprises simultaneously exposing the substrate to vacuum ultraviolet radiation and to an ambient gas. The ambient gas comprises nitrogen and hydrogen-containing gas or argon-containing gas. Accordingly, the gap filling fluid is cured to form silicon nitride in the gap. It shall be understood that silicon nitride can refer to a crystalline or amorphous ceramic that substantially consists of silicon and nitrogen. Optionally, silicon nitride can comprise hydrogen. In some embodiments, silicon nitride refers to a material that substantially consists of crosslinked polysilazanes.

A method of curing a gap filling fluid can be suitably executed in the context of methods for filling a gap. Thus, further described herein is a method of filling a gap. The method comprises introducing a substrate provided with a gap into a process system. The method further comprises executing one or more cycles. A cycle comprises a deposition step and a curing step. The deposition step comprises providing a precursor. The precursor comprises silicon, nitrogen, and hydrogen. The deposition step further comprises providing a reactant. The reactant comprises one or more of nitrogen, hydrogen, and a noble gas. The deposition step further comprises generating a plasma. The plasma causes the precursor and the reactant to react to form a gap filling fluid that at least partially fills the gap. It shall be understood that the plasma can be generated in a process chamber comprising a substrate. The plasma can be in direct contact with the substrate, i.e. it can be used in a direct plasma configuration. Alternatively, the plasma can be separated from the substrate using a porous barrier such as a mesh plate or a perforated plate. The plasma can also be generated at a remote location which is operationally connected to the process chamber that comprises the substrate, and active species can be provided from that remote location to the process chamber such that the substrate can be exposed to those active species. The gap filling fluid thus formed comprises a silicon-nitrogen bond. The curing step comprises simultaneously exposing the substrate to vacuum ultraviolet radiation and to an ambient gas. The ambient gas comprises nitrogen and hydrogen-containing gas or argon-containing gas Thus, the gap filling fluid is cured and silicon nitride is formed in the gap.

In some embodiments, the method includes entirely filling the gap with silicon nitride. In some embodiments, the method includes filling the gap with silicon nitride without the formation of voids. In other words, in some embodiments, the deposition according to the present methods is continued until the gap is fully filled with silicon nitride, and substantially no voids are formed in the filled gap. The presence of voids can be observed by studying the formed material in a scanning tunneling electron microscope.

In some embodiments, a gap filling fluid can be formed using a direct plasma, and can then be cured. Thus further described herein is a method of filling a gap. A method as described herein can comprise introducing a substrate provided with a gap into a process system. The method further comprises executing one or more cycles. A cycle comprises a deposition step and a curing step. The deposition step comprises exposing the substrate to a precursor. The precursor comprises silicon, nitrogen, and hydrogen. The deposition step further comprises exposing the substrate to a reactant. The reactant comprises one or more of nitrogen, hydrogen, and a noble gas. The deposition step further comprises generating a plasma. Thus, the precursor and the reactant react in the presence of the plasma to form a gap filling fluid. The gap filling fluid at least partially fills the gap and comprises a Si—N bond. In some embodiments, the filling capability can be accomplished by forming a viscous material in a gas phase by striking, for example, a noble gas, N₂ and/or NH₃ plasma, in a chamber filled with a volatile precursor that can be polymerized within certain parameter ranges. Optionally the gas phase comprises a further gas apart from the precursor, and a noble gas, N₂ and/or NH₃, for example H₂. The curing step comprises simultaneously exposing the substrate to vacuum ultraviolet radiation and to an ambient gas. The ambient gas comprises nitrogen and hydrogen-containing gas or argon-containing gas. Thus, the gap filling fluid is cured and silicon nitride is formed in the gap.

In some embodiments, the plasma is a direct capacitively-coupled RF plasma generated between a showerhead precursor injector located in the process chamber on the one hand and the substrate on the other hand. In some embodiments, a plasma power of at least 10 W to at most 300 W is used for forming the gap filling fluid. In some embodiments, a plasma power of at least 20 W to at most 150 W is used for forming the gap filling fluid. In some embodiments, a plasma power of at least 30 W to at most 100 W is used for forming the gap filling fluid. In some embodiments, a plasma power of at least 35 W to at most 75 W is used for forming the gap filling fluid. In some embodiments, a plasma power of at least 40 W to at most 50 W is used for forming the gap filling fluid. It shall be understood that these powers are provided for the special case of 300 mm wafers. They can be readily converted to units of W/cm² to obtain equivalent RF power values for different wafer sizes.

Suitably, in a direct plasma configuration, the process chamber can comprise a substrate support and a showerhead injector. The substrate support and the showerhead injector can be parallelly arranged and can be separated by an electrode gap. In some embodiments, an electrode gap of at least 5 mm to at most 30 mm, e.g. an electrode gap of at least 5 mm to at most 10 mm, or an electrode gap of at least 10 mm to at most 20 mm, or an electrode gap of at least 20 mm to at most 30 mm is used.

In some embodiments, a method as described herein can comprise generating a plasma that is not in direct contact with the substrate. Exemplary configurations include indirect plasma and remote plasma configurations, and are described elsewhere herein in more detail.

In some embodiments, comprises executing a plurality of cycles. Accordingly, the gap is at least partially filled with silicon nitride. In some embodiments, the gap is entirely filled with silicon nitride.

In some embodiments, the nitrogen and hydrogen-containing gas comprises ammonia (NH₃). In some embodiments, the nitrogen and hydrogen-containing gas comprises hydrazine (N₂H₂). In some embodiments, the nitrogen and hydrogen-containing gas substantially consists of at least one of ammonia and hydrazine. It shall thus be understood that the nitrogen and hydrogen can be comprised in one and the same compound. Furthermore, it shall be understood that the nitrogen and hydrogen-containing gas can comprise further gasses such as one or more noble gasses such as Ar or He.

In some embodiments, the curing step is carried out at a curing temperature which is at most 20° C. higher than the deposition temperature.

Flowable films may be temporarily obtained when a volatile precursor is polymerized by a plasma and deposited on a surface of a substrate, wherein gaseous precursor (e.g. monomer) is activated or fragmented by energy provided by plasma gas discharge so as to initiate polymerization, and when the resultant material is deposited on the surface of the substrate, the material temporarily shows flowable behavior.

It shall be understood that the gap filling fluid can be described as a viscous material, i.e. a viscous phase that is formed on the substrate. The gap filling fluid is capable of flowing in a trench on the substrate. Suitable substrates include silicon wafers. As a result, the viscous material seamlessly fills the trench in a bottom-up way.

In some embodiments, the gap filling fluid consists of silicon, nitrogen, hydrogen, and optionally one or more halogens. In other words, and in some embodiments, the gap filling fluid consists of silicon, nitrogen, and hydrogen; whereas in other embodiments, the gap filling fluid consists of silicon, nitrogen, hydrogen, and one or more halogens.

In some embodiments, the gap filling fluid comprises a polysilazane. In some embodiments, the gap filling fluid comprises a polysilazane oligomer. The polysilazane oligomer may be branched or linear. Suitably, the polysilazane oligomer comprises a plurality of oligomeric species, i.e. the gap filling fluid may comprise various different oligomers, both branched and linear. In some embodiments, a polysilazane oligomer comprises a plurality of different macromolecules that may have a varying morphology.

The gap filling fluids that are formed herein comprise hydrogen. In some embodiments, the gap filling fluids that are formed herein comprise from at least 3% to at most 30% H, or from at least 5% to at most 20% H, or from at least 10% to at most 15% H, wherein all percentages are given in atomic percent. Hence, when, for example, a gap filling fluid is referred to as SiN, the breath of the term “SiN” is intended to encompass SiN:H, i.e. SiN comprising hydrogen, e.g. up to 30 atomic percent hydrogen.

Suitable precursors include precursors that consist of silicon, nitrogen, and hydrogen, and optionally one or more halogens. In other words, suitable precursors comprise compounds that contain no other atoms apart from silicon atoms, nitrogen atoms, hydrogen atoms, and optionally one or more halogens.

In some embodiments, the precursor does not contain any carbon, halogens, or chalcogens. In some embodiments, the precursor does not contain any carbon or chalcogens. In some embodiments, the precursor does not contain any carbon. In some embodiments, the precursor does not contain any chalcogens. For example, in some embodiments, the precursor does not contain any carbon, chlorine, or oxygen.

Advantageously, the precursor does not contain any atoms other than silicon, nitrogen, and hydrogen. In other words, in some embodiments, the precursor essentially consists of silicon, nitrogen, and hydrogen.

In some embodiments, the precursor comprises a silazane.

In some embodiments, the precursor comprises a compound having the formula

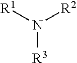

It shall be understood that R¹, R², and R³ are independently selected from SiH₃, SiH₂X, SiHXY, SiX₂Y, and SiX₃, that X is a first halogen, and that Y is a second halogen. In some embodiments, R¹, R², and R³ are SiH₃. In some embodiments, the first halogen and/or the second halogen are selected from the list consisting of fluorine, chlorine, bromine, and iodine. In some embodiments, the first halogen and/or the second halogen is fluorine. In some embodiments, the first halogen and/or the second halogen is chlorine. In some embodiments, the first halogen and/or the second halogen is bromine. In some embodiments, the first halogen and/or the second halogen is iodine. In some embodiments, at least one of R¹, R², and R³ is SiH₃. In some embodiments, the precursor comprises trisilylamine. When trisilylamine is used as a precursor, the reactant may be suitably selected from the list consisting of N₂, NH₃, Ar, and He.

In some embodiments, the precursor comprises a compound having the formula

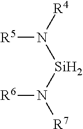

It shall be understood that R⁴, R⁵, R⁶, and R⁷ are independently selected from H, SiH₃, SiH₂X, SiHXY, SiX₂Y, and SiX₃. It shall be further understood that X is a first halogen, and that Y is a second halogen. In some embodiments, R⁴, R⁵, R⁶, and R⁷ are SiH₃. In some embodiments, R⁴, R⁵, R⁶, and R⁷ are H. In some embodiments, the first halogen and/or the second halogen are selected from the list consisting of fluorine, chlorine, bromine, and iodine. In some embodiments, the first halogen and/or the second halogen is fluorine. In some embodiments, the first halogen and/or the second halogen is chlorine. In some embodiments, the first halogen and/or the second halogen is bromine. In some embodiments, the first halogen and/or the second halogen is iodine. In some embodiments, at least one of R⁴, R⁵, R⁶, and R⁷ is SiH₃. In some embodiments, R⁴ and R⁷ are SiH₃ and R⁵ and R⁶ are H. In some embodiments, R⁴, R⁵, R⁶, and R⁷ are H.

In some embodiments, the precursor comprises a cyclosilazane. Gapfill layers using cyclosilazane precursors provide layers with particularly good lateral flowability, i.e. particularly good flowability in lateral spaces. Suitably, the cyclosilazane only comprises silicon, nitrogen, hydrogen, and optionally a halogen such as chlorine.

In some embodiments, the cyclosilazane comprises a ring structure selected from the group consisting of a cyclotrisilazane ring, a cyclotetrasilazane ring, and a cyclopentasilazane ring.

In some embodiments, the precursor comprises a compound having the formula

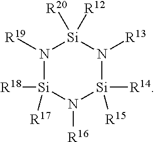

It shall be understood that R¹², R¹³, R¹⁴, R¹⁵, R¹⁶, R¹⁷, R¹⁸, R¹⁹, and R²⁰ are independently selected from the list consisting of H, X, Y, NH₂, SiH₃, SiH₂X, SiHXY, SiX₂Y, and SiX₃, wherein X is a first halogen, and wherein Y is a second halogen. In some embodiments, the first halogen and/or the second halogen are selected from the list consisting of fluorine, chlorine, bromine, and iodine. In some embodiments, the first halogen and/or the second halogen is fluorine. In some embodiments, the first halogen and/or the second halogen is chlorine. In some embodiments, the first halogen and/or the second halogen is bromine. In some embodiments, the first halogen and/or the second halogen is iodine. In some embodiments, at least one of R¹², R¹³, R¹⁴, R¹⁵, R¹⁶, R¹⁷, R¹⁸, R¹⁹, and R²⁰ is H. In some embodiments, R¹², R¹³, R¹⁴, R¹⁵, R¹⁶, R¹⁷, R¹⁸, R¹⁹, and R²⁰ are H.

In some embodiments, the precursor consists of silicon, nitrogen, and hydrogen; and the gap filling fluid consists of silicon, nitrogen, and hydrogen. In some embodiments, the precursor further comprises one or more halogens, and the gap filling fluid further comprises one or more halogens. In some embodiments, the precursor consists of silicon, nitrogen, hydrogen, and one or more halogens; and the gap filling fluid consists of silicon, nitrogen, hydrogen, and one or more halogens. It shall be understood that, when the gap filling fluid consists of certain components, other components may, in some embodiments, still be present in small quantities, e.g. as contaminants.

It shall be understood that the reactant is not necessarily incorporated in the gap filling fluid which is deposited. Thus, in some embodiments the reactant is incorporated in the gap filling fluid whereas in other embodiments, the reactant is not incorporated in the gap filling fluid. For example, when a noble gas such as argon is used as a reactant, the noble gas is not substantially incorporated in the gap filling fluid.

In some embodiments, the reactant comprises nitrogen, hydrogen, ammonia, hydrazine, one or more noble gasses, or a mixture thereof.

In some embodiments, the reactant comprises at least one of nitrogen and ammonia.

In some embodiments, the reactant comprises a noble gas.

In some embodiments, the noble gas is selected from the list consisting of He, Ne, Ar, and Kr.

In some embodiments, the noble gas is Ar.

In some embodiments, the precursor and the reactant are simultaneously provided. For example, the precursor and the reactant can be simultaneously provided to a process chamber. In some embodiments, the reactant is a carrier gas. It shall be understood that a carrier gas refers to a gas that carries, or entrains, a precursor to the process chamber. An exemplary carrier gas includes a noble gas such as argon. Exemplary carrier gas flow rates are of at least 0.1 slm to at most 10 slm, or of at least 0.1 slm to at most 0.2 slm, or of at least 0.2 slm to at most 0.5 slm, or of at least 0.5 slm to at most 1.0 slm, or of at least 1.0 slm to at most 2.0 slm, or of at least 2.0 slm to at most 5.0 slm, or of at least 5.0 slm to at most 10.0 slm, or of at least 0.1 slm to at most 2 slm.

In some embodiments, all gases supplied to the reaction space while forming a gap filling fluid are the precursor, the reactant, an optional carrier such as N₂, Ar, and/or He, and an optional plasma ignition gas which can be or include Ar, He, N₂, and/or H₂. In other words, no other gasses are provided to the process chamber than those listed, in these embodiments. In some embodiments, the carrier gas and/or the plasma ignition gas functions as a reactant. In some embodiments, the precursor consists of silicon, nitrogen, and hydrogen.

In some embodiments, the reactant comprises nitrogen and ammonia, and no gasses other than the precursor and the reactant are introduced into the process chamber during the deposition step.

In some embodiments, the reactant comprises a noble gas such as He or Ar, and no gasses other than the precursor and the reactant are introduced into the process chamber during the deposition step.

In some embodiments, the deposition step and the curing step are carried out in the same process system, without any intervening vacuum break.

In some embodiments, the deposition step is carried out in a first process chamber and the curing step is carried out in a second process chamber. It shall be understood that the first process chamber and the second process chamber are different process chambers comprised in the same process system.

In some embodiments, the vacuum ultraviolet radiation comprises electromagnetic radiation having a wavelength of at least 140 nm to at most 200 nm. For example, the vacuum ultraviolet (VUV) radiation can have a peak intensity at a wavelength of at least 10 nm to at most 200 nm, or of at least 10 nm to at most 50 nm, or of at least 50 nm to at most 100 nm, or of at least 100 nm to at most 150 nm, or of at least 150 nm to at most 200 nm. For example, when (SiH₃)₂NSiH₂N(SiH₃)₂, is used as a silicon precursor and NH₃ is used as nitrogen and hydrogen-containing gas, then VUV light with a wavelength between 130 and 200 nm, such as VUV light with a wavelength between 140 nm and 190 nm, or as VUV light with a wavelength between 150 nm and 180 nm, is preferably used.

In some embodiments, a volatile precursor is polymerized within a certain parameter range mainly defined by partial pressure of precursor during a plasma strike, wafer temperature, and total pressure in the process chamber. In order to adjust the “precursor partial pressure”, an indirect process knob (dilution gas flow) may be used to control the precursor partial pressure. The absolute number of precursor partial pressure may not be required in order to control flowability of deposited film, and instead, a ratio of flow rate of precursor to flow rate of the remaining gas and the total pressure in the reaction space at a reference temperature and total pressure can be used as practical control parameters. The above notwithstanding, and in some embodiments, the process chamber is maintained during gapfill fluid formation at a pressure of at least 600 Pa to at most 10000 Pa. For example, the pressure in the process chamber may be maintained at a pressure of at least 600 Pa to at most 1200 Pa, or at a pressure of at least 1200 Pa to at most 2500 Pa, or at a pressure of at least 2500 Pa to at most 5000 Pa, or at a pressure of at least 5000 Pa to at most 10000 Pa.

In some embodiments, the deposition step is executed at a temperature of at least −25° C. to at most 200° C. In some embodiments, the deposition step is executed at a temperature of at least −25° C. to at most 0° C. In some embodiments, the deposition step is executed at a temperature of at least 0° C. to at most 25° C. In some embodiments, the deposition step is executed at a temperature of at least 25° C. to at most 50° C. In some embodiments the deposition step is executed at a temperature of at least 50° C. to at most 75° C. In some embodiments, the deposition step is executed at a temperature of at least 75° C. to at most 150° C. In some embodiments, the deposition step is executed at a temperature of at least 150° C. to at most 200° C. This enhances the gap filling properties of the presently provided gap filling fluids. In some embodiments, the deposition step is executed at a temperature of at least 70° C. to at most 90° C., or at a temperature of at least 80° C. to at most 100° C. In some embodiments, the deposition step is carried out at a deposition temperature of at most 150° C.

The precursor source can comprise a precursor recipient, e.g. a precursor canister, a precursor bottle, or the like; and one or more gas lines operationally connecting the precursor recipient to the process chamber. Accordingly, the precursor recipient may be suitably maintained at a temperature which is from at least 5° C. to at most 50° C. lower than the temperature of the process chamber, or at a temperature which is from at least 5° C. to at most 10° C. lower than the temperature of the process chamber, or at a temperature which is from at least 10° C. to at most 20° C. lower than the temperature of the process chamber, or at a temperature which is from at least 30° C. to at most 40° C. lower than the temperature of the process chamber, or at a temperature which is from at least 40° C. to at most 50° C. lower than the temperature of the process chamber. The gas lines may be suitably maintained at a temperature between the temperature of the precursor recipient and the process chamber. For example, the gas lines may be maintained at a temperature which is from at least 5° C. to at most 50° C., or from at least 5° C. to at most 10° C., or from at least 10° C. to at most 20° C., or from at least 30° C. to at most 40° C., or from at least 40° C. to at most 50° C. lower than the temperature of the process chamber. In some embodiments, the gas lines and the process chamber are maintained at a substantially identical temperature which is higher than the temperature of the precursor recipient.

A plasma as used herein, whether remote, indirect, or direct; whether capacitively coupled or inductively coupled, can be generated by means of an alternating current operating at a plasma frequency. In some embodiments, a plasma frequency of at least 40 kHz to at most 2.45 Ghz is used, or a plasma frequency of at least 40 kHz to at most 80 kHz is used, or a plasma frequency of at least 80 kHz to at most 160 kHz is used, or a plasma frequency of at least 160 kHz to at most 320 kHz is used, or a plasma frequency of at least 320 kHz to at most 640 kHz is used, or a plasma frequency of at least 640 kHz to at most 1280 kHz is used, or a plasma frequency of at least 1280 kHz to at most 2500 kHz is used, or a plasma frequency of at least 2.5 MHz to at least 5 MHz is used, or a plasma frequency of at least 5 MHz to at most 50 MHz is used, or a plasma frequency of at least 5 MHz to at most 10 MHz is used, or a plasma frequency of at least 10 MHz to at most 20 MHz is used, or a plasma frequency of at least 20 MHz to at most 30 MHz is used, or a plasma frequency of at least 30 MHz to at most 40 MHz is used, or a plasma frequency of at least 40 MHz to at most 50 MHz is used, or a plasma frequency of at least 50 MHz to at most 100 MHz is used, or a plasma frequency of at least 100 MHz to at most 200 MHz is used, or a plasma frequency of at least 200 MHz to at most 500 MHz is used, or a plasma frequency of at least 500 MHz to at most 1000 MHz is used, or a plasma frequency of at least 1 GHz to at most 2.45 GHz is used. In exemplary embodiments, the plasma is a capacitive RF plasma, and RF power is provided at a frequency of 13.56 MHz.

In some embodiments, a deposition step comprises simultaneously introducing a precursor and a reactant.

In some embodiments, present methods include exposing the gap filling fluid to a radio frequency (RF) plasma, e.g. using a plasma frequency of 15 MHz or lower, and make used of a cyclic deposition process employing pulsed precursor flow and a pulsed RF plasma. The precursor pulses and the plasma pulses may be separated by purge gas pulses. In some embodiments, the duration of the purge steps and the flow rate of purge gas is selected to be sufficiently low as to ensure that not all precursor has been removed from the process chamber after the purge step has finished. In other words, the duration of the purge steps and purge gas flow rates used therein can be sufficiently low such that the entire process chamber is not evacuated during a purge step. Preferably, the reactant is used as a purge gas. In such embodiments, the desired aspects for flowability of depositing film include: 1) high enough partial pressure during the entire RF-on period for polymerization to progress; 2) sufficient energy to activate the reaction (defined by the RF-on period and RF power), during an RF period which is not too long; 3) temperature and pressure for polymerization/chain growth set above the melting point and below the boiling point of the flowable phase; 4) temperature and pressure for polymerization chain growth selected at sufficiently low levels such that the gap filling fluid has sufficient time to fill the gap before it solidifies, e.g. due to chain growth.

In some embodiments, the present methods involve providing the precursor intermittently to the reaction space, and continuously applying a plasma. In some embodiments, the present methods involve providing the precursor intermittently to the reaction space, and intermittently applying a plasma. The latter embodiments thus feature the sequential application of precursor pulses and plasma pulses to the reaction space.

In some embodiments, the present methods involve providing the precursor continuously to the reaction space, and continuously or cyclically applying a plasma, e.g. through application of RF power, throughout the deposition step. The plasma may be continuous or pulsed, and it may be direct or remote.

In some embodiments, the deposition step comprises providing the precursor continuously to the process chamber, continuously providing the reactant to the process chamber, and continuously providing a plasma in the process chamber.

In some embodiments, the deposition step employs alternating precursor and plasma pulses.

In some embodiments, a pulsed plasma, e.g. a pulsed RF plasma is used during the deposition step. In some embodiments, the period of RF power application (i.e. the period in which reactants in the reactor are exposed to plasma) is in the range of at least 0.7 seconds to at most 2.0 seconds, for example from at least 0.7 seconds to at most 1.5 seconds.

In some embodiments, the deposition step comprises one or more deposition cycles. A deposition cycle comprises a sequence of a precursor pulse, an optional precursor purge, a plasma pulse, and an optional post plasma purge, which are continually repeated.

In some embodiments, the duration of the precursor pulse, i.e. the precursor feed time, is from at least 0.25 s to at most 4.0 s, or from at least 0.5 s to at most 2.0 s, or from at least 1.0 s to at most 1.5 s.

In some embodiments, the duration of the purge step directly after the precursor pulse, i.e. the precursor purge time, is from at least 0.025 s to at most 2.0 s, or from at least 0.05 s to at most 0.8 s, or from at least 0.1 s to at most 0.4 s, or from at least 0.2 s to at most 0.3 s. This timing can apply both for the case when N₂ and/or NH₃ is used as a reactant, and when a noble gas such as Ar is used as a reactant.

In some embodiments, a method as described herein comprising a step of annealing the substrate at an annealing temperature, the annealing temperature being higher than the deposition temperature. Preferably, vacuum is not broken between formation of the gap filling fluid and the anneal. The anneal can be carried out in the same process chamber as the process chamber in which the gap filling fluid is formed, or in a different process chamber located in the same system as the process chamber in which the gap filling fluid is formed. The anneal can be carried out after all gap filling fluid has been deposited, in between subsequent deposition cycles, after some but not all of the gap filling fluid has been deposited, before a curing step, or after a curing step. Suitable annealing times include from at least 10.0 seconds to at most 10.0 minutes, for example from at least 20.0 seconds to at most 5.0 minutes, for example from at least 40.0 seconds to at most 2.5 minutes. Suitably, the anneal is performed in a gas mixture comprising one or more gasses selected from the list consisting of N₂, He, Ar, and H₂. In some embodiments, the anneal is carried out in an atmosphere that comprises a nitrogen-containing gas such as N₂. In some embodiments, the anneal is carried out at a temperature of at least 200° C., or at a temperature of at least 250° C., or at a temperature of at least 300° C., or at a temperature of at least 350° C., or at a temperature of at least 400° C., or at a temperature of at least 450° C. in some embodiments, the anneal is carried out at a temperature of at least 100° C. to at most 550° C., or at a temperature of at least 100° C. to at most 375° C., or at a temperature of at least 375° C. to at most 550° C.

Further described herein is a processing system comprising a first process chamber, a precursor source, a precursor line, an ammonia source, an ammonia line, and a vacuum ultraviolet light source. The precursor source comprises a precursor. The precursor can be any precursor described herein and comprises aa Si—N bond. The precursor line is arranged for providing the precursor from the precursor source to the first process chamber. The ammonia line is arranged for providing ammonia from the ammonia source to the first process chamber. The vacuum ultraviolet light source is arranged for generating vacuum ultraviolet light.

In some embodiments, the system comprises a second process chamber and a wafer handling system. In such embodiments, the vacuum ultraviolet light source can suitably be arranged for providing vacuum ultraviolet light to the second process chamber, and the wafer handling system can be arranged for transporting one or more wafers between the first process chamber and the second process chamber.

In some embodiments, the system further comprises a controller. The controller is arranged for causing the processing system to carry out a method as described herein.

In an exemplary embodiment, a gap filling fluid is formed using direct plasma polymerization of (SiH₃)₂NSiH₂N(SiH₃)₂, i.e. of a compound having the following structure formula:

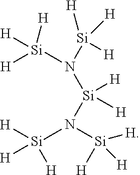

Without the present invention or disclosure being limited by any particular theory or mode of operation, it is believed that the direct plasma polymerization results in formation of an oligomeric silazane and/or polysilazane-containing gap filling fluid. After the gap filling fluid has been formed, the gap filling fluid is exposed to vacuum ultraviolet light. Thus, the wet etch rate ratio of the gap filling fluid is improved from at least 40.3 to 10.6. Additionally, film shrinkage upon annealing at high temperatures (400° C.) is improved from 7.1% to 4.1%. Fourier Transform Infrared Spectroscopy (FTIR) measurements indicate significant changes in the Si—H and Si—N peak parameters when comparing uncured and cured gap filling fluids. This indicates that the gap filling fluid undergoes chemical changes such as at least one of cross-linking and further polymerization reactions, which is correlated to overall improvement of the properties of the gap filling fluid.

It shall be understood that wet etch rate ratios (WERR) as reported herein are obtained by dipping samples in diluted HF acid (dHF 1:100), measuring layer thicknesses in an electron microscope, and comparing the sample etch rates relative to those of thermally grown silicon oxide on a monocrystalline silicon wafer. In other words, wet etch rate ratio is obtained by measuring the wet etch rate of a sample layer, measuring the wet etch rate of a thermal silicon oxide reference in the same etchant, and dividing the wet etch rate obtained for the sample by that obtained for the reference.

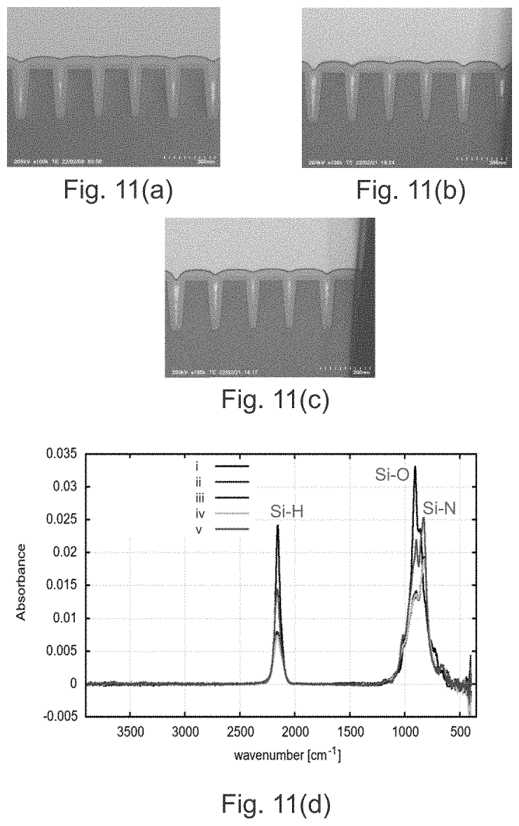

FIGS. 11(a)-11(d) show experimental results. All experimental results were obtained by first forming a gap filling fluid using (SiH₃)₂NSiH₂N(SiH₃)₂ as a silicon precursor in a capacitively-coupled direct plasma setup using a substrate temperature of 90° C., a process time of 50 s, and a plasma gas that comprised Ar and N₂. For all samples, the gap filling formation step and subsequent VUV exposure step occurred in different process chambers comprised in the same vacuum system without any intervening vacuum break. VUV exposure was performed using light having a peak intensity at 172 nm, and a power density of 25 mW/cm² was employed for 10 minutes. During VUV exposure, the VUV process chamber was maintained at a pressure of 300 Pa, and a substrate temperature of 100° C. was used.

In particular, FIG. 11(a) shows a scanning transmission electron micrograph of a sample that was processed according to a method as described herein. After gap filling fluid formation, the sample was simultaneously exposed to ammonia (NH₃) and to vacuum ultraviolet (VUV) light. This resulted in a cured gap filling fluid having a wet etch rate ratio in diluted HF (1 vol % HF in H₂O at 22.5° C.) of >36.45, a shrinkage of only 4.5% upon anneal at 400° C. in a reduced N₂ atmosphere at a pressure of 120 Pa for 30 minutes, a refractive index of 1.667, a deposition rate (D/R) of 1.650 nm/s, and a mean thickness of cured gap filling fluid of 82.5 nm as measured by ellipsometry by averaging thickness measurements on 5 different positions on a blanket layer on a substrate. FIG. 11(b) shows a scanning transmission electron micrograph of a comparative sample that was subjected to simultaneous exposure to Ar and VUV light after gap filling fluid formation. This resulted in a cured gap filling fluid having a wet etch rate ratio of >22.88, a shrinkage of 2.5% upon anneal as described before, a refractive index of 1.650, a D/R of 0.948 nm/s, and a mean thickness of cured gap filling fluid of 47.4 nm. FIG. 11(c) shows a scanning transmission electron micrograph of a comparative sample that was subjected to simultaneous exposure to H₂ and VUV light after gap filling fluid formation. This resulted in a cured gap filling fluid having a wet etch rate ratio of >27.23, a shrinkage of 0%, a refractive index of 1.666, a D/R of 0.990 nm/s, and a mean thickness of cured gap filling fluid of 49.5 nm. Advantageously, a gap filling fluid cured using VUV light and an NH₃ exposure has a lower wet etch rate ratio, less void formation, a lower shrinkage upon anneal, and a higher thickness of cured gap filling fluid for the same processing time.

FIG. 11(d) shows Fourier Transform Infrared Spectroscopy (FTIR) spectra for several samples. In particular, spectrum i shows an FTIR spectrum for as-deposited gap filling fluid, without any cure; spectrum ii shows an FTIR spectrum for gap filling fluid that was cured by simultaneous Ar and VUV exposure; spectrum iii shows an FTIR spectrum for gap filling fluid that was cured by simultaneous N₂ and VUV exposure; spectrum iv shows an FTIR spectrum for a gap filling fluid that was cured by simultaneous H₂ and VUV exposure; and, spectrum v shows an FTIR spectrum for a gap filling fluid that was cured by simultaneous NH₃ and VUV exposure. The FTIR measurements indicate H and/or Si removal from the gap filling fluid upon NH₃ and VUV exposure, indicating a possible loss of SiH₃ groups. In addition, the measurements indicate nitridation, i.e. polymerization, of the gap filling fluid on NH₃ and VUV exposure.

For all samples, the wet etch rate ratio was measured using elliposometry. For all samples, shrinkage was measured using thickness measurements after anneal at 400° C. in a reduced N₂ atmosphere at a pressure of 120 Pa for 30 minutes, refractive index was measured using ellipsometry, D/R was measured using thickness measurements taking into account deposition time, and mean thickness of the cured gap filling fluid was measured using ellipsometry measurements on five different positions on a substrate comprising a blanket film of interest.

It shall be understood that while the simultaneous NH₃ and VUV exposure still resulted in void formation, a larger portion of gap filling fluid was cured in one curing sequence using simultaneous NH₃ and VUV exposure compared to other curing approaches. Thus, it is expected that the presently disclosed methods, when carried out in a cyclical deposition-cure mode, can result in voidless silicon nitride gapfill formation, with “silicon nitride” referring to a crystalline or amorphous silicon nitride, or to a crosslinked polysilazane resin, or to an intermediate material. Advantageously, “silicon nitride” formed using the presently disclosed methods can have a very low to a negligible carbon content. For example, the carbon content of silicon nitride formed using a method as disclosed herein can be less than 1 atomic percent, or less than 0.1 atomic percent, or less than 0.01 atomic percent, or less than 10-4 atomic percent, or less than 10-8 atomic percent.

According to further experimental results, not shown in figures, were obtained by first forming a gap filling fluid using (SiH₃)₂NSiH₂N(SiH₃)₂ as a silicon precursor in a capacitively-coupled direct plasma setup using a substrate temperature of 90° C., a process time of 50 s, and a plasma gas that comprised Ar and N₂. For all samples, the gap filling formation step and subsequent VUV exposure step occurred in different process chambers comprised in the same vacuum system without any intervening vacuum break. VUV exposure was performed using light having a peak intensity at 172 nm, and a power density of 125 mW/cm² was employed for 6 minutes. During VUV exposure, the VUV process chamber was maintained in an argon environment, at a pressure of 1200 Pa, and a substrate temperature of 80° C. was used.

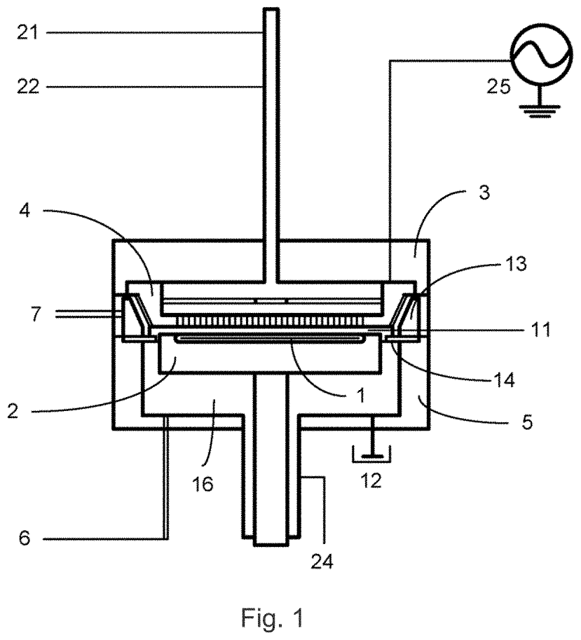

A gap filling fluid may be formed in any suitable apparatus, including in a reactor as shown in FIG. 1. FIG. 1 is a schematic view of an apparatus for plasma-enhanced cyclic depositions, desirably in conjunction with controls programmed to conduct the sequences described below, usable in some embodiments of the present invention. In this figure, by providing a pair of electrically conductive flat-plate electrodes (2,4) in parallel and facing each other in the interior (11) (reaction zone) of a process chamber (3), applying RF power (e.g. at 13.56 MHz and/or 27 MHz) from a power source (25) to one side, and electrically grounding the other side (12), a plasma is excited between the electrodes. A temperature regulator may be provided in a lower stage (2), i.e. the lower electrode. A substrate (1) is placed thereon and its temperature is kept constant at a given temperature. The upper electrode (4) can serve as a shower plate as well, and a reactant gas and/or a dilution gas, if any, as well as a precursor gas can be introduced into the process chamber (3) through a gas line (21) and a gas line (22), respectively, and through the shower plate (4). Additionally, in the process chamber (3), a circular duct (13) with an exhaust line (17) is provided, through which the gas in the interior (11) of the process chamber (3) is exhausted. Additionally, a transfer chamber (5) is disposed below the process chamber (3) and is provided with a gas seal line (24) to introduce seal gas into the interior (11) of the process chamber (3) via the interior (16) of the transfer chamber (5) wherein a separation plate (14) for separating the reaction zone and the transfer zone is provided. Note that a gate valve through which a wafer may be transferred into or from the transfer chamber (5) is omitted from this figure. The transfer chamber is also provided with an exhaust line (6).

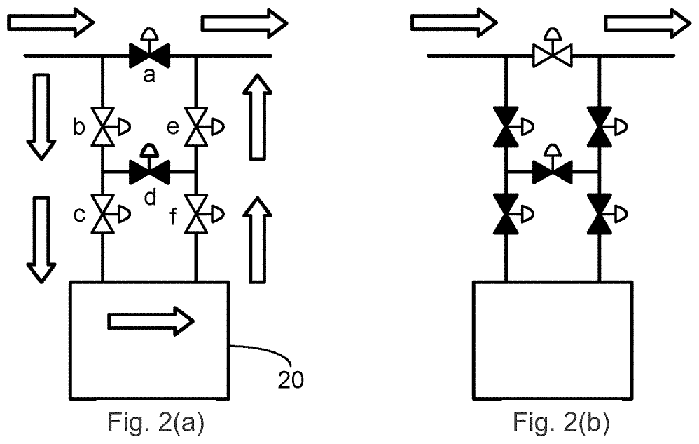

In some embodiments, the apparatus depicted in FIG. 1, the system of switching flow of an inactive gas and flow of a precursor gas illustrated in FIGS. 2(a) and 2(b) can be used to introduce the precursor gas in pulses without substantially fluctuating pressure of the process chamber.

Indeed, a continuous flow of the carrier gas can be accomplished using a flow-pass system (FPS) wherein a carrier gas line is provided with a detour line having a precursor reservoir (bottle), and the main line and the detour line are switched, wherein when only a carrier gas is intended to be fed to a process chamber, the detour line is closed, whereas when both the carrier gas and a precursor gas are intended to be fed to the process chamber, the main line is closed and the carrier gas flows through the detour line and flows out from the bottle together with the precursor gas. In this way, the carrier gas can continuously flow into the process chamber and can carry the precursor gas in pulses by switching the main line and the detour line. FIGS. 2(a) and 2(b) illustrate a precursor supply system using a flow-pass system (FPS) according to an embodiment of the present invention (black valves indicate that the valves are closed). As shown in FIG. 2(a), when feeding a precursor to a process chamber (not shown), first, a carrier gas such as Ar (or He) flows through a gas line with valves b and c, and then enters a bottle (reservoir) (20). The carrier gas flows out from the bottle (20) while carrying a precursor gas in an amount corresponding to a vapor pressure inside the bottle (20) and flows through a gas line with valves f and e and is then fed to the process chamber together with the precursor. In the above, valves a and d are closed. When feeding only the carrier gas (which can be a noble gas such as He or Ar) to the process chamber, as shown in FIG. 2(b), the carrier gas flows through the gas line with the valve a while bypassing the bottle (20). In the above, valves b, c, d, e, and f are closed.

As noted, a skilled artisan will appreciate that the apparatus includes one or more controller(s) (not shown) programmed or otherwise configured to cause the deposition process described elsewhere herein to be conducted. The controller(s) communicate with the various power sources, heating systems, pumps, robotics and gas flow controllers or valves of the reactor, as will be appreciated by the skilled artisan. The controller(s) include electronic circuitry including a processor, and software to selectively operate valves, manifolds, heaters, pumps and other components included in the system. Such circuitry and components operate to introduce precursors, reactants, and optionally purge gases from the respective sources (e.g., bottle 20). The controller can control timing of gas supply sequences, temperature of the substrate and/or process chamber (3), pressure within the process chamber (3), and various other operations to provide proper operation of the system. The controller(s) can include control software to electrically or pneumatically control valves to control flow of precursors, reactants and purge gases into and out of the process chamber (3). Controller(s) can include modules such as a software or hardware component, e.g., a FPGA or ASIC, which performs certain tasks. It shall be understood that where the controller includes a software component to perform a certain task, the controller is programmed to perform that particular task. A module can advantageously be configured to reside on the addressable storage medium, i.e. memory, of the control system and be configured to execute one or more processes.

Optionally, a dual chamber reactor can be used. A dual chamber reactor comprises two sections or compartments for processing wafers disposed close to each other. In such a dual chamber reactor, a reactant gas and a noble gas can be supplied through a shared line and precursor-containing gases are provided by means of unshared lines. In exemplary embodiments, forming a gap filling fluid occurs in one of the two compartments, and the step of curing occurs in another process chamber. This can advantageously improve throughput, e.g. when gap filling fluid formation and curing occur at different temperatures.

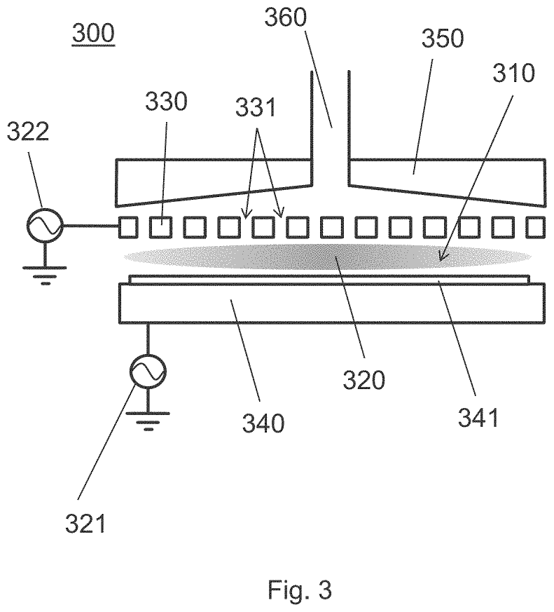

FIG. 3 shows a schematic representation of an embodiment of a direct plasma system (300) that is operable or controllable to form a gap filling fluid. The system (300) includes a process chamber (310) in which a plasma (320) is generated. In particular, the plasma (320) is generated between a showerhead injector (330) and a substrate support (340) supporting a substrate or wafer (341).

In the configuration shown, the system (300) includes two alternating current (AC) power sources: a high frequency power source (321) and a low frequency power source (322). In the configuration shown, the high frequency power source (321) supplies radio frequency (RF) power to the showerhead injector, and the low frequency power source (322) supplies an alternating current signal to the substrate support (340). The radio frequency power can be provided, for example, at a frequency of 13.56 MHz or higher. The low frequency alternating current signal can be provided, for example, at a frequency of 2 MHz or lower.

Process gas comprising precursor, reactant, or both, can be provided through a gas line (360) to a conical gas distributor (350). The process gas then passes via through holes (331) in the showerhead injector (330) to the process chamber (310). Whereas the high frequency power source (321) is shown as being electrically connected to the showerhead injector and the low frequency power source (322) is shown as being electrically connected to the substrate support (340), other configurations are possible as well. For example, in some embodiments (not shown), both the high frequency power source and the low frequency power source can be electrically connected to the showerhead injector; both the high frequency power source and the low frequency power source can be electrically connected to the substrate support; or both the high frequency power source can be electrically connected to the substrate support, and the low frequency power source can be electrically connected to the showerhead injector.

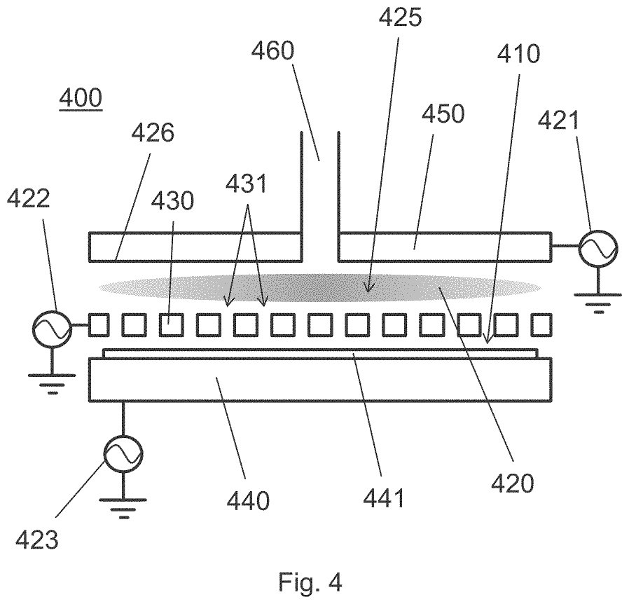

FIG. 4 shows a schematic representation of another embodiment of an indirect plasma system (400) operable or controllable to form a gap filling fluid. The system (400) includes a process chamber (410), which is separated from a plasma generation space (425) in which a plasma (420) is generated. In particular, the process chamber (410) is separated from the plasma generation space (425) by a showerhead injector (430), and the plasma (420) is generated between the showerhead injector (430) and a plasma generation space ceiling (426).

In the configuration shown, the system (400) includes three alternating current (AC) power sources: a high frequency power source (421) and two low frequency power sources (422), (423) (i.e., a first low frequency power source (422) and a second low frequency power source (423)). In the configuration shown, the high frequency power source (421) supplies radio frequency (RF) power to the plasma generation space ceiling, the first low frequency power source (422) supplies an alternating current signal to the showerhead injector (430), and the second low frequency power source (423) supplies an alternating current signal to the substrate support (440). A substrate (441) is provided on the substrate support (440). The radio frequency power can be provided, for example, at a frequency of 13.56 MHz or higher. The low frequency alternating current signal of the first and second low frequency power sources (422), (423) can be provided, for example, at a frequency of 2 MHz or lower.

Process gas comprising precursor, reactant, or both, is provided through a gas line (460) that passes through the plasma generation space ceiling (426) to the plasma generation space (425). Active species such as ions and radicals generated by the plasma (420) from the process gas pass via through holes (431) in the showerhead injector (430) to the process chamber (410).

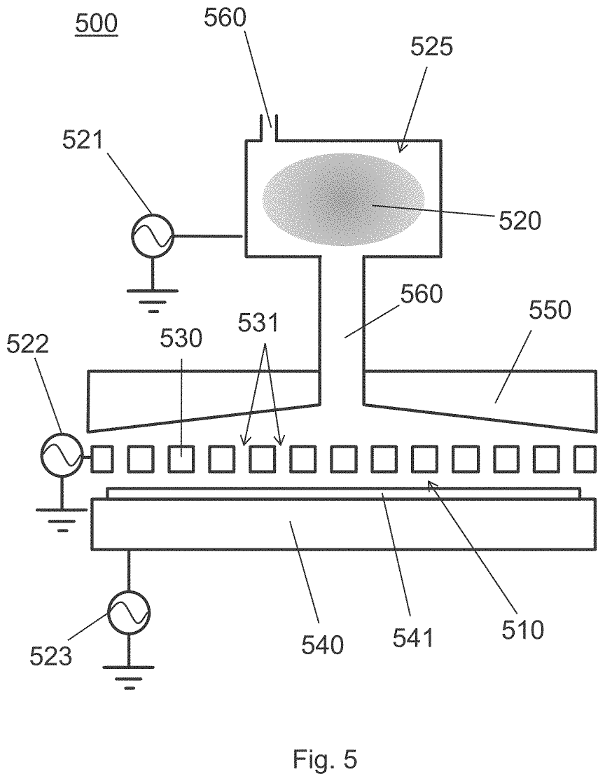

FIG. 5 shows a schematic representation of an embodiment of a remote plasma system (500) operable or controllable to form a gap filling fluid. The system (500) includes a process chamber (510), which is operationally connected to a remote plasma source (525) in which a plasma (520) is generated. Any sort of plasma source can be used as a remote plasma source (525), for example an inductively coupled plasma, a capacitively coupled plasma, or a microwave plasma. In particular, active species are provided from the plasma source (525) to the process chamber (510) via an active species duct (560) to a conical distributor (550) via through holes (531) in a shower plate injector (530) to the process chamber (510). Thus, active species can be provided to the process chamber in a uniform way.

In the configuration shown, the system (500) includes three alternating current (AC) power sources: a high frequency power source (521) and two low frequency power sources (522, 523) (e.g., a first low frequency power source (522) and a second low frequency power source (523)). In the configuration shown, the high frequency power source (521) supplies radio frequency (RF) power to the plasma generation space ceiling, the first low frequency power source (522) supplies an alternating current signal to the showerhead injector (530), and the second low frequency power source (523) supplies an alternating current signal to the substrate support (540). A substrate (541) is provided on the substrate support (540). The radio frequency power can be provided, for example, at a frequency of 10 MHz or higher. The low frequency alternating current signal of the first and second low frequency power sources (522), (523) can be provided, for example, at a frequency of 2 MHz or lower. In some embodiments (not shown), an additional high frequency power source can be electrically connected to the substrate support. Thus, a direct plasma can be generated in the process chamber. Process gas comprising precursor, reactant, or both, is provided to the plasma source (525) by means of a gas line (560). Active species such as ions and radicals generated by the plasma (520) from the process gas are guided to the process chamber (510).

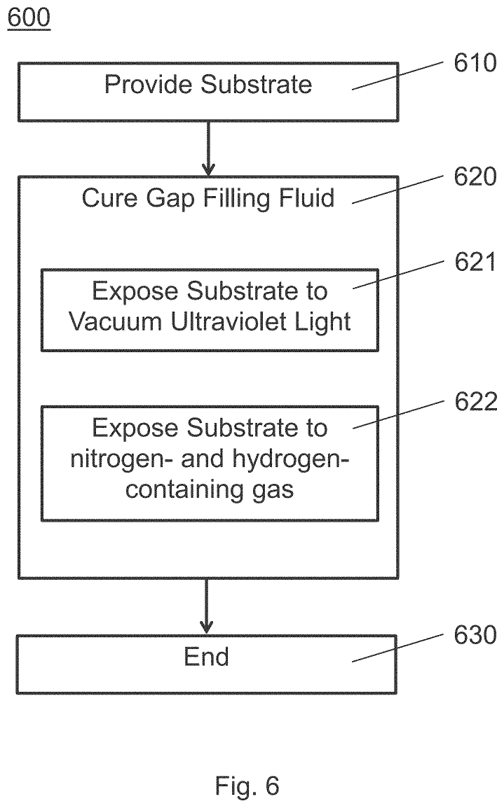

FIG. 6 shows an exemplary embodiment of a method (600) for curing a gap filling fluid as described herein. The method (600) comprises a step of providing a substrate in a process chamber. The substrate is provided with a gap. The gap comprises a gap filling fluid. The gap filling fluid comprises a silicon-nitrogen (Si—N) bond. The method then comprises a step (620) of curing the gap filling fluid. The step (620) of curing the gap filling fluid comprises exposing (621,622) the substrate to vacuum ultraviolet light and to a nitrogen- and hydrogen-containing gas. Then, the method (600) according to the present exemplary embodiment ends.

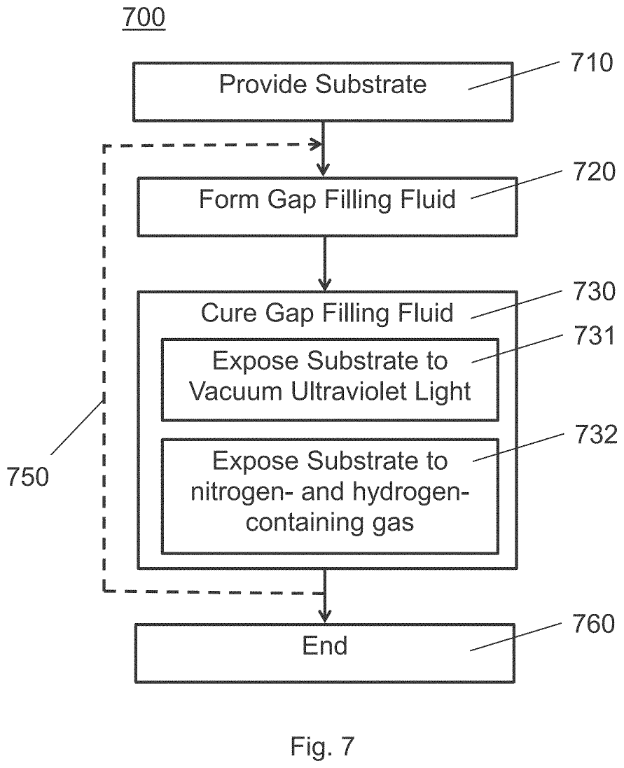

FIG. 7 shows another exemplary embodiment of a method (700) for curing a gap filling fluid as described herein. The method (700) comprises a step of providing a substrate in a process chamber. The method then comprises executing one or more cycles (750). A cycle (750) comprises a step (720) of forming a gap filling fluid and a step (730) of curing the gap filling fluid. In other words, the method comprises a step (720) of forming a gap filling fluid and a step (730) of curing the gap filling fluid, and these steps (720,730) can optionally be repeated (750) one or more times. The step (720) of forming the gap filling fluid comprises providing a precursor, providing a reactant, and generating a plasma. The precursor comprises silicon, nitrogen, and hydrogen. The reactant comprises nitrogen, hydrogen, and a noble gas. The plasma causes the precursor and the reactant to react. Thus, a gap filling is formed. The gap filling fluid at least partially fills the gap. The gap filling fluid comprises a Si—N bond. The step (730) of curing the gap filling fluid comprises simultaneously exposing (731,732) the substrate to vacuum ultraviolet light and to a nitrogen- and hydrogen-containing gas.

Optionally, more than one cycle (750) can be executed, i.e. optionally the steps (720,730) of forming and curing the gap filling fluid can be repeated (750) one or more times. This can be useful, for example, for filling a gap with silicon nitride having a particularly low wet etch rate ratio. When the gap has been filled with a suitable amount of material, the method ends (760).

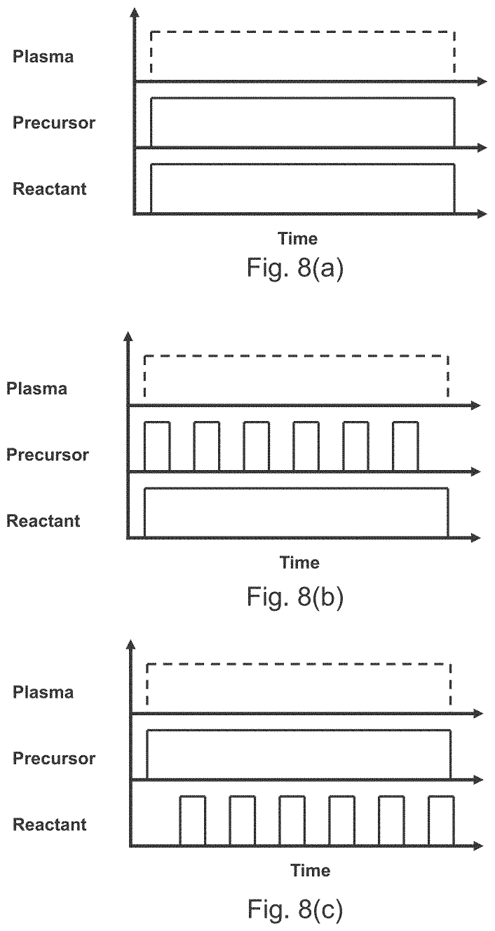

FIGS. 8(a)-8(c) show exemplary pulsing schemes that can be used for forming gap filling fluids in one or more embodiments of methods as described herein. In each of these embodiments, a plasma is generated, and can be used, for example, in a direct, indirect, or remote configuration. The plasma can be operated continuously or in a pulsed manner. FIG. 8(a) shows a flow scheme in which precursor and reactant are continuously provided to the process chamber, i.e. there is no pulsing of precursor or reactant flow. Both thermal and plasma-enhanced chemical vapor deposition methods can employ such a continuous precursor or reactant provision. FIG. 8(b) shows a flow scheme in which precursor flow is pulsed and reactant flow is continuous. FIG. 8(c) shows a pulsing scheme in which precursor flow is continuous and reactant flow is pulsed. The flow schemes of FIGS. 8(b) and 8(c) can be used in pulsed thermal or plasma-enhanced chemical vapor deposition approaches of forming a liner.

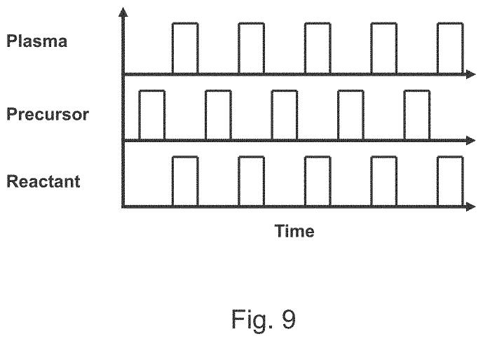

FIG. 9 shows another exemplary pulsing scheme that can be used for forming a gap filling fluid in one or more embodiments of methods as described herein. In particular, the substrate is exposed to precursor and reactant in non-overlapping precursor pulses and reactant pulses, respectively. Optionally, the precursor pulses and the reactant pulses are separated by purges. In some embodiments (not shown) the precursor and reactant pulses partially overlap. A plasma is generated in a plurality of plasma pulses, and could be used, for example, in a direct, indirect, or remote configuration. During the plasma pulses, the substrate is exposed to plasma-generated active species such as ions or radicals. In some embodiments, the plasma pulses at least partially overlap with at least one of the precursor purses and the reactant pulses. In the embodiment shown, the plasma pulses overlap with the reactant pulses, i.e. the plasma is generated at the same time as the reactant is provided.

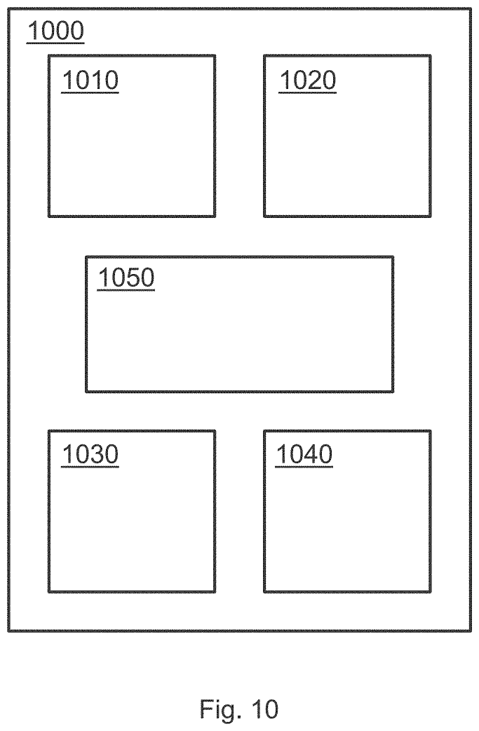

FIG. 10 schematically shows a layout of an exemplary system (1000) according to an embodiment of the present disclosure. The system (1000) comprises a gapfill chamber (1010). The gapfill chamber (1010) is arranged for forming a gap filling fluid. Exemplary embodiments of gap filling chambers are shown in FIGS. 1, 3, 4, and 5. The system (1000) further comprises a VUV chamber (1020). The VUV chamber (1020) comprises a vacuum ultraviolet light source which is arranged for exposing a substrate to vacuum ultraviolet light. The system (1000) further comprises an annealing chamber (1030). The annealing chamber (1030) is arranged for thermally treating the substrate. The annealing chamber (1030) comprises one or more heating elements. Suitable heating elements include resistive heaters comprised in a substrate support and infrared light sources. The system (1000) further comprises a load lock (1040). The load lock (1040) can be suitably used for bringing substrates into the system, and for taking substrates out of the system. The system (1000) further comprises a substrate transfer chamber (1050). The substrate transfer chamber (1050) can be employed for transporting substrates between the load lock (1040), the gapfill chamber (1010), the VUV chamber (1020), and the annealing chamber (1030).

In some embodiments, the substrate transfer chamber (1050) is omitted. In such embodiments, substrates can be transported directly between the gapfill chamber (1010), the VUV chamber (1020), and the annealing chamber (1030).

In some embodiments, the annealing chamber (1030) is omitted. In such embodiments, an ex-situ anneal can be used for further improving the quality of material that is used for filling gaps. Alternatively, an anneal can be omitted altogether, and a VUV treatment as such can be used for transforming a gap filling fluid into a high quality material.

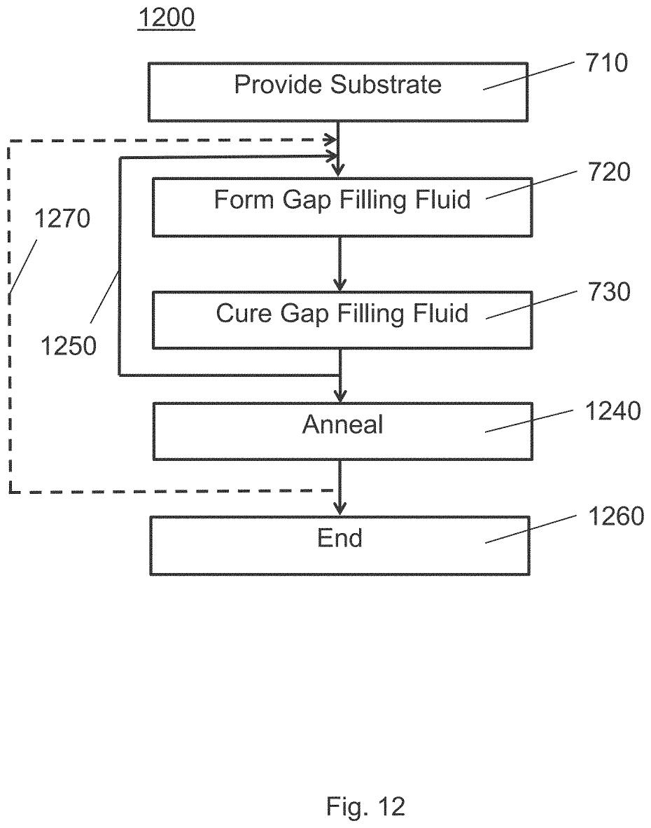

FIG. 12 shows another exemplary embodiment of a method (1200) for curing a gap filling fluid as described herein. The method (1200) comprises a step of providing a substrate in a process chamber. The method then comprises executing a plurality of cycles (1250). A cycle (1250) comprises a step (1220) of forming a gap filling fluid and a step (1230) of curing the gap filling fluid. In other words, the method comprises a step (1220) of forming a gap filling fluid and a step (1230) of curing the gap filling fluid, and these steps (1220,1230) are repeated (1250) one or more times. The step (1220) of forming the gap filling fluid comprises providing a precursor, providing a reactant, and generating a plasma. The precursor comprises silicon, nitrogen, and hydrogen. The reactant comprises nitrogen, hydrogen, and a noble gas. The plasma causes the precursor and the reactant to react. Thus, a gap filling fluid is formed. The gap filling fluid at least partially fills the gap. The step (1230) of curing the gap filling fluid comprises simultaneously exposing the substrate to vacuum ultraviolet light and to a nitrogen- and hydrogen-containing gas such as ammonia. After the plurality of cycles (1250) has been executed, the substrate is annealed using an anneal as described herein. Optionally, carrying out the plurality of cycles (1250) and the annealing step (1240) is repeated one or more times, thereby forming a plurality of super cycles (1270). When the gap has been filled with a suitable amount of material, the method ends (1260).

Although certain embodiments and examples have been discussed, it will be understood by those skilled in the art that the scope of the claims extend beyond the specifically disclosed embodiments to other alternative embodiments and/or uses and obvious modifications and equivalents thereof. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

In the present disclosure, where conditions and/or structures are not specified, the skilled artisan in the art can readily provide such conditions and/or structures in view of the present disclosure, as a matter of routine experimentation.

What is claimed is:

1. A method of curing a gap filling fluid, the method comprising:
introducing in a process chamber a substrate provided with a gap, the gap comprising a gap filling fluid, the gap filling fluid comprising a Si—N bond; and
simultaneously exposing the substrate to vacuum ultraviolet radiation and to an ambient gas;
thereby curing the gap filling fluid and forming silicon nitride in the gap.

2. A method of filling a gap comprising:
introducing a substrate provided with a gap into a process system;
executing one or more cycles, a cycle comprising a deposition step and a curing step, the deposition step comprising:
providing a precursor, the precursor comprising silicon, nitrogen, and hydrogen;
providing a reactant, wherein the reactant comprises one or more of nitrogen, hydrogen, and a noble gas; and,
generating a plasma; whereby the plasma causes the precursor and the reactant to react to form a gap filling fluid that at least partially fills the gap, the gap filling fluid comprising a Si—N bond;
the curing step comprising:
simultaneously exposing the substrate to vacuum ultraviolet radiation and to an ambient gas, thereby curing the gap filling fluid and forming silicon nitride in the gap, wherein the ambient gas is a nitrogen and hydrogen-containing gas or an argon-containing gas.

3. The method according to claim 2 wherein the method comprises executing a plurality of cycles, thereby at least partially filling the gap with silicon nitride.

4. The method according to claim 2 wherein the nitrogen and hydrogen-containing gas comprises NH₃.

5. The method according to claim 1 wherein the gap filling fluid comprises a polysilazane.

6. The method according to claim 2 wherein the precursor comprises a silazane.

7. The method according to claim 2 wherein the precursor comprises a compound having a formula 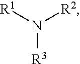
wherein R¹, R², and R³ are independently selected from SiH₃, SiH₂X, SiH₂XY, SiX₂Y, and SiX₃,
wherein X is a first halogen, and wherein Y is a second halogen.

8. The method according to claim 7 wherein R¹, R², and R³ are SiH₃.

9. The method according to claim 2 wherein the precursor comprises a compound having a formula 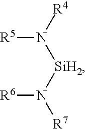
wherein R⁴, R⁵, R⁶, and R⁷ are independently selected from H, SiH₃, SiH₂X, SiHXY, SiX₂Y, and SiX₃,
wherein X is a first halogen, and wherein Y is a second halogen.

10. The method according to claim 2 wherein the precursor comprises a compound having a formula 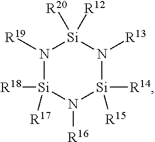
wherein R¹², R¹³, R¹⁴, R¹⁵, R¹⁶, R¹⁷, R¹⁸, R¹⁹, and R²⁰ are independently selected from a list consisting of H, X, Y, NH₂, SiH₃, SiH₂X, SiHXY, SiX₂Y, and SiX₃, wherein X is a first halogen, and
wherein Y is a second halogen.

11. The method according to claim 2 wherein the deposition step and the curing step are carried out in the same process system, without any intervening vacuum break.

12. The method according to claim 1 wherein the vacuum ultraviolet radiation comprises electromagnetic radiation with a wavelength of at least 150 nm to at most 200 nm.

13. The method according to claim 2 wherein the deposition step is carried out in a first process chamber, wherein the curing step is carried out in a second process chamber, and wherein the first process chamber and the second process chamber are different process chambers comprised in the same process system.

14. The method according to claim 2 wherein the deposition step is carried out at a deposition temperature of at most 150° C.

15. The method according to claim 1 wherein the curing step is carried out at a curing temperature which is at most 20° C. higher than a deposition temperature.

16. The method according to claim 1 further comprising a step of annealing the substrate at an annealing temperature, the annealing temperature being higher than a deposition temperature.

17. A processing system comprising a first process chamber, a precursor source, a precursor line, an ammonia source, an ammonia line, and a vacuum ultraviolet light source; wherein
the precursor source comprises a precursor, the precursor comprising a Si—N bond;
the precursor line being arranged for providing the precursor from the precursor source to the first process chamber;
the ammonia line being arranged for providing ammonia from the ammonia source to the first process chamber; and,
the vacuum ultraviolet light source being arranged for generating vacuum ultraviolet light.

18. The processing system according to claim 17 further comprising a second process chamber, and a wafer handling system, the vacuum ultraviolet light source being arranged for providing vacuum ultraviolet light to the second process chamber, the wafer handling system being arranged for transporting one or more wafers between the first process chamber and the second process chamber.

19. The processing system according to claim 17 further comprising a controller, the controller being arranged for causing the processing system to carry out a method comprising:
introducing in the first process chamber a substrate provided with a gap, the gap comprising a gap filling fluid, the gap filling fluid comprising a Si—N bond; and
simultaneously exposing the substrate to vacuum ultraviolet radiation and to an ambient gas;
thereby curing the gap filling fluid and forming silicon nitride in the gap.

20. The processing system according to claim 17 further comprising a controller, the controller being arranged for causing the processing system to carry out a method comprising:
introducing a substrate provided with a gap into a process system;
executing one or more cycles, a cycle comprising a deposition step and a curing step, the deposition step comprising:
providing a precursor, the precursor comprising silicon, nitrogen, and hydrogen;
providing a reactant, wherein the reactant comprises one or more of nitrogen, hydrogen, and a noble gas; and
generating a plasma; whereby the plasma causes the precursor and the reactant to react to form a gap filling fluid that at least partially fills the gap, the gap filling fluid comprising a Si—N bond;
the curing step comprising:
simultaneously exposing the substrate to vacuum ultraviolet radiation and to an ambient gas, thereby curing the gap filling fluid and forming silicon nitride in the gap, wherein the ambient gas is a nitrogen and hydrogen-containing gas or an argon-containing gas.
